(19) United States
(12) Patent Application Publication
(10) Pub. No.: US 2026/0012009 A1
(43) Pub. Date: Jan. 8, 2026

(54) POWER SWITCH SHORT CIRCUIT PROTECTION

(71) Applicant: Visic Technologies Ltd., Ness Ziona (IL)

(72) Inventors: Dmitry Novo, Kibbutz Beit-Govrin (IL); Gleb Vetakh, Ashdod (IL); Shahar Wagner, Ein-Vered (IL); David Shapiro, Rishion LeZion (IL)

(21) Appl. No.: 18/762,716

(22) Filed: Jul. 3, 2024

(51) Int. Cl. H02H 9/04

(52) U.S. Cl. CPC H02H 9/044

(57) ABSTRACT

Short circuit protection circuitry comprising: a HEMT (high electron mobility transistor) comprising a source, drain, and gate controllable to be turned ON and OFF by voltage applied to the gate; a comparator having an input coupled to a high-pass filter and an output at which the comparator generates an output signal responsive to a voltage induced across an inductance if the voltage after filtering by the filter exhibits a voltage surge greater than a threshold voltage; and a voltage divider controllable to be turned ON and turned OFF to control voltage provided to the gate of the HEMT, and wherein the voltage divider is turned ON responsive to the output signal from the comparator to provide the gate with a reduced voltage that is less than an ON-threshold voltage of the HEMT.

### FIELD

Embodiments of the invention relate to providing short circuit protection to a power switch.

### BACKGROUND

Modern optical and electronic devices of almost all types, from computers to powertrains, comprise power switching circuitry for generating timing pulses, data packets, and/or delivering power. For delivering power to electric powertrains, such as powertrains used to deliver power to electric vehicles, power switches are required that can rapidly be turned ON and OFF to couple and decouple a high voltage electric power source to a load. Group III-V high electron mobility transistors (HEMTs), for example GaN (gallium nitride) transistors, are particularly advantageous for such applications. Group III-V HEMTs are wide band gap transistors characterized by high breakdown voltage, high current density, and low ON-state resistance that are operable at high frequencies suitable for providing power to operate a modern automotive electric powertrain traction engine.

Whereas HEMTs may be normally ON, depletion mode (D-mode) or normally OFF enhancement mode (E-mode) transistors, for high power and current switching applications D-mode HEMTs are often advantageous because inter alia they are characterized by lower ON-resistance (Rₒₙ) and are able to support greater current densities. However, since D-mode HEMTs are normally ON power switching circuitry that use HEMT transistors as switching elements, require a controller to be in constant control of the ON/OFF states of the transistors and maintain them OFF as long as they are coupled to a power source and not required to be ON to switch power from the power source to a load. For high frequency switching applications, such for powering an automotive electric traction engine, the controller is generally required to switch them between ON and OFF at high frequencies with high temporal resolution.

In the absence of such control, for example if the switching circuitry is connected to the power source before being connected to the controller, or the controller or the HEMT transistor malfunctions during operation, large current transients and/or short circuits may be generated that damage the power switch, the load, and/or the power source.

### SUMMARY

An aspect of an embodiment of the disclosure relates to providing a power switch comprising a HEMT transistor and short circuit protection circuitry configured to detect with relatively small latency onset of a short circuit in a circuit comprising the power switch, and rapidly respond to the detection to mediate and prevent development of the short circuit. The short circuit protection circuitry may be referred to as “Short-Stop” circuitry or simply “Short-Stop”.

In an embodiment the power switch comprises a cascode having a D-mode (depletion mode) HEMT connected in series with a MOSFET (metal on semiconductor field effect transistor). When the power switch operates to couple a load to a DC power source, a controller comprised in the power switch turns the MOSFET transistor ON and switches the HEMT transistor ON and OFF to power the load with pulses of voltage from the power supply. The voltage pulses may, by way of example, be pulse width modulated (PWM) pulses configured to power the load with power that varies at a desired frequency substantially harmonically with time. The Short-Stop comprises a comparator that generates an output signal responsive to voltage generated by current in the cascode flowing through stray inductance of the MOSFET. When current through the MOSFET stray inductance generates a fast risetime surge voltage that exceeds a predetermined voltage threshold indicating onset of a short circuit, Short-Stop operates to turn OFF the HEMT transistor and shut down current through the cascode. Optionally, Short-Stop operates first to moderate current through the cascode and then turns OFF the HEMT to prevent current through the cascode and thereby continued development of the short circuit.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter

### BRIEF DESCRIPTION OF THE FIGURES

Non-limiting examples of embodiments of the invention are described below with reference to figures attached hereto that are listed following this paragraph. Identical structures, elements or parts that appear in more than one figure are generally labeled with a same numeral in all the figures in which they appear. Dimensions of components and features shown in the figures are chosen for convenience and clarity of presentation and are not necessarily shown to scale.

FIG. 1A shows a schematic of a power switch comprising a cascode protected by a Short-Stop and operating to couple a power source to a load, in accordance with an embodiment of the disclosure; and

FIG. 1B schematically shows the power switch and Short-Stop shown in FIG. 1A with the Short-Stop detecting onset of a short circuit and operating to moderate and then shut down current through the cascode, in accordance with an embodiment of the disclosure.

### DETAILED DESCRIPTION

In the discussion, unless otherwise stated, adjectives such as “substantially” and “about” modifying a condition or relationship characteristic of a feature or features of an embodiment of the disclosure, are understood to mean that the condition or characteristic is defined to within tolerances that are acceptable for operation of the embodiment for an application for which it is intended. Wherever a general term in the disclosure is illustrated by reference to an example instance or a list of example instances, the instance or instances referred to, are by way of non-limiting example instances of the general term, and the general term is not intended to be limited to the specific example instance or instances referred to. The phrase “in an embodiment”, whether or not associated with a permissive, such as “may”, “optionally”, or “by way of example”, is used to introduce for consideration an example, but not necessarily a required configuration of possible embodiments of the disclosure. Unless otherwise indicated, the word “or” in the description and claims is considered to be the inclusive “or” rather than the exclusive or, and indicates at least one of, or any combination of more than one of items it conjoins.

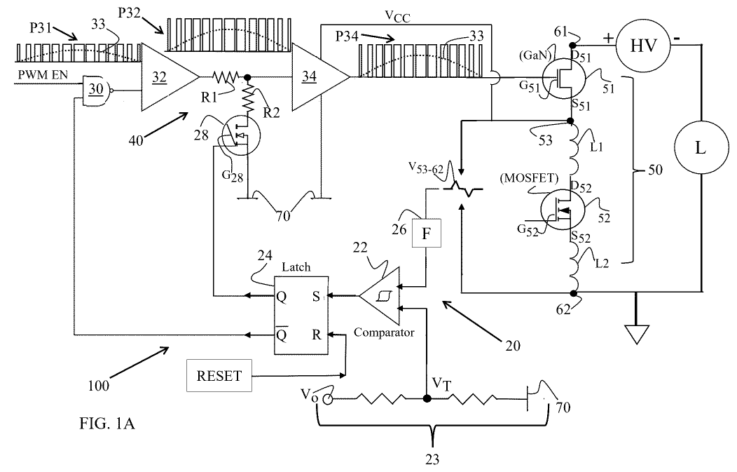

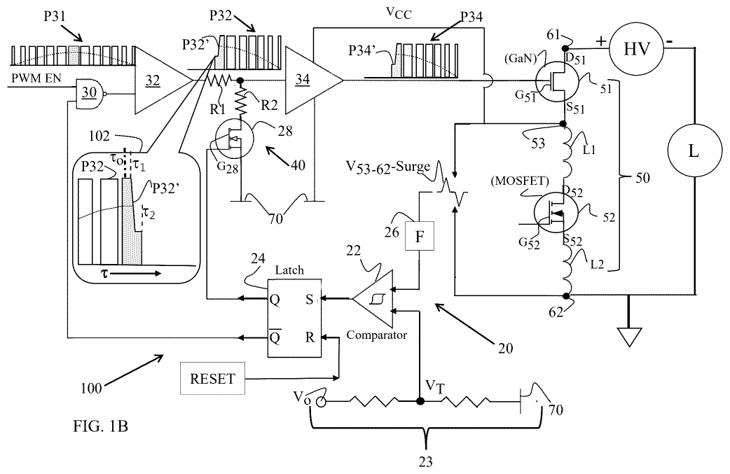

FIG. 1A schematically shows a power switch 100 comprising a cascode 50 and a Short-Stop 20, operating to power a load L with power from an optionally high voltage power supply HV, in accordance with an embodiment of the disclosure. Optionally, cascode 50 is connected between nodes 61 and 62 in series with power supply HV and load L. In an embodiment the cascode comprises a HEMT, optionally a D-mode, n-channel GaN transistor 51, connected in series at an intermediate node 53 with an optionally n-channel MOSFET transistor 52. HEMT 51 has a source S₅₁, gate G₅₁, and drain D₅₁. MOSFET 52 has a source S₅₂, gate G₅₂, and drain D₅₂ and is characterized by drain and source stray inductances L1 and L2 respectively. Short-Stop 20 optionally comprises a comparator 22, a latch 24, and a voltage divider circuit 40.

HEMT gate G₅₁ is connected to a gate driver 32 optionally by a buffer 34. Buffer 34 is connected to the gate driver via voltage divider circuit 40, which may comprise resistances R1 and R2 and a switch, optionally an n-channel MOSFET transistor 28. A power supply (not shown) provides node 53 and a top rail voltage of buffer 34 with a same voltage V_{CC} relative to a signal ground 70. Gate driver 32 generates and transmits output signals P32 to buffer 34 responsive to input signals P31 when enabled by enable signals from, optionally, a NAND circuit 30. Optionally, as schematically shown in FIG. 1A, input signals P31 are PWM positive pulses and output signals P32 propagated to buffer 34 are corresponding positive PWM pulses having voltage referred to as voltage V-P32. Buffer 34 generates output pulses that bias gate G₅₁ to control the ON/OFF state of HEMT 51 responsive to voltage pulses that it receives from gate driver 32. Optionally, pulses generated by buffer 34 are proportional to pulses received from gate driver 32. Optionally, buffer 34 is a buffer voltage follower.

When transistor 28 is OFF as schematically indicated in FIG. 1A by the “raised” gate G28 of transistor 28 voltage divider 40 is OFF and substantially only R1 of the voltage divider affects voltage of pulses P32 that reach buffer 34 from gate driver 32. Voltage of pulses P32 reaching buffer 34 when voltage divider 40 is OFF have a voltage optionally referred to as voltage V-P32, and in response to pulses P32 reaching buffer 34 the buffer generates pulses P34 having voltage V-P34. When transistor 28 is ON, as schematically indicated in FIG. 1B discussed below, pulses generated by gate driver 32 that reach buffer 34 after passing through R1 have voltage reduced by a factor R2/(R1+R2) and are referred to as reduced voltage pulses P32′ characterized by a reduced voltage V-P32′. In response to receiving a reduced voltage pulse P32′, buffer 34 generates a reduced pulse P34′ that exhibits a reduced voltage V-P34′.

A reduced voltage pulse P32′ may exhibit reduced voltage, V-P32′ for only a portion of its duration if voltage divider circuitry 40 is turned on during the pulse width of a “parent” pulse P32 from which it is produced. A reduced voltage pulse P32′ may exhibit reduced voltage V-P32′ for all of its duration if voltage divider circuitry 40 is turned on prior to the beginning of the parent pulse. Similarly, a reduced voltage pulse P34′ generated by buffer 34 responsive to a received voltage pulse P32′ from gate driver 32 may exhibit reduced voltage for all or only a portion of the pulse width of P34′.

In an embodiment, resistors R1 and R2 of the voltage divider may be determined subject to the following constraints: 1) when voltage divider 40 is OFF, voltage V-P34 of pulses P34 that the buffer 34 generates responsive to pulses P32 that have passed through R1 bias gate G₅₁ to turn ON HEMT 51; 2) when the voltage divider is turned ON, buffer 34 generates a pulse or pulses P34′ having reduced voltage V-P34′ that is below the ON-threshold of HEMT 51 by a moderate voltage difference ΔV, so that decrease of current through cascode 50 due to drop in voltage delivered by buffer 34 to gate G₅₁ operates to reduce probability of large voltage transients; and 3) when turned ON, voltage divider resistance R1+R2 is advantageously large enough to prevent drawing a magnitude of current from gate driver 32 that may injure the gate driver.

Coupling gate driver 32 to HEMT gate G₅₁ via buffer 34, in accordance with an embodiment of the disclosure, enables relatively large values for voltage divider resistances R1 and R2 that provide advantageous reduction of voltage of pulses 32 when the voltage divider is ON. And when the voltage divider is OFF, the buffer decouples voltage pulses from gate driver 32 that have lost energy in passing through R1 from directly biasing gate G₅₁ and replaces the pulses with voltage pulses from buffer 34 to provide robust ON/OFF switching of HEMT 51.

In an embodiment, a ratio R2/R1 may have a value between 0.2 to about 0.3, R1 a value between about 50-150 ohms; and ΔV a value between about 10% to about 30% of an absolute value of an ON-threshold voltage of HEMT transistor 51. By way of example, assuming that HEMT 51 is a GaN D-mode HEMT having an ON-threshold voltage typically between −3 volts to about −11 volts, ΔV may have a value between about 0.5 volts to about 4 volts.

In an embodiment ON/OFF states of switch 28 and output of enable circuit NAND 30 are controlled by logical levels of outputs Q and Q̅ (Q-bar) respectively of latch 24. Latch 24 receives set, “SET”, signals from comparator 22 and receives reset, “RESET”, signals generated manually or by a processor (not shown) that initialize the latch. Comparator 22 is coupled to voltage V₅₃₋₆₂ between node 53 and node 62, optionally via a high pass filter 26, and to a threshold voltage V_{T}, optionally determined by a voltage Vₒ and a voltage divider 23. High pass filter 26 is characterized by a passband that passes frequencies expected to characterize a surge of voltage V₅₃₋₆₂ between nodes 53 and 62 generated by stray inductances L1 and L2 responsive to a fast rise in current through cascode 50 associated with an onset of short-circuiting power source HV and attenuates frequencies characterizing normal operation of power switch 100. In an embodiment the passband has a lower bound cutoff frequency that is greater than a frequency characterizing a slew rate of current through MOSFET 52 during normal operation of power switch 100.

Under normal operation in the absence of an onset of a short circuit, as schematically shown in FIG. 1A, voltage V₅₃₋₆₂ that is input to comparator 22 after filtering by high-pass filter 26 does not exceed threshold V_{T}, the comparator does not generate a SET signal for latch 24 and Q and Q-bar of the latch optionally present 0 and 1 logical levels respectively. As a result, responsive to the logical 1 received from Q-bar outputs and an enable signal PWM EN, NAND 30 generates an enable signal that enables gate driver 32 and responsive to the logical 0 received by voltage divider circuit 40 from Q, MOSFET 28 is maintained OFF. PWM input pulses P31 input to gate driver 32 therefore generate voltage pulses P32 from the gate driver which in turn generate corresponding voltage output pulses P34 from buffer 34 at gate G₅₁ that pulse HEMT 51 ON to power load L with voltage pulses from power source HV. Optionally, as schematically indicated by curved dashed lines 33 voltage pulses P31, P32, and P34, provide power to the load that varies substantially harmonically with time at a desired frequency.

On the other hand, in the event of an onset of a short circuit, as schematically indicated in FIG. 1B, voltage V₅₃₋₆₂ between node 53 and node 62 exhibits a surge voltage, “V₅₃₋₆₂-surge”, and when the surge voltage filtered by high-pass filter 26 exceeds threshold voltage V_{T}, comparator 22 generates a SET signal that sets Q and Q-bar outputs to logical 1 and 0. Logical 1 from Q turns ON MOSFET 28 and thereby voltage divider 40, and following a delay, the logical 0 from Q-bar causes NAND 30 to generate a disable signal that disables gate driver 32. Optionally, the delay is a latency delay generated by signal processing and propagation delay characterizing operation of NAND 30 and/or gate driver 32.

As noted above, turning ON voltage divider 40 reduces voltage of pulses P32 from gate driver 32 to reduced voltage V-P32′ of reduced pulses P32′ and results in biasing HEMT 51 gate G₅₁ relative to source S₅₁ of HEMT 51 by reduced voltage V-P34′ of pulses P34′. Subsequent disabling of gate driver 32 by NAND 30 stops generation of pulses by the gate driver and buffer 34 and turns OFF HEMT 51. FIG. 1B schematically illustrates a case for which a surge voltage, V₅₃₋₆₂-surge, indicating a short circuit in accordance with an embodiment is recognized by Short-Stop 20 during a pulse P32 shown shaded in the figure. As a result, logical levels from latch 24 turn ON voltage divider 40, to turn the pulse P32 into a decreased voltage pulse P32′, also shown shaded, cause buffer 34 to bias gate G₅₁ with voltage V-P34′ from a reduced voltage pulse P34′ and prevent further generation of pulses that turn ON HEMT 51.

An inset 102 in the figure shows an enlarged image of pulses P32 and P32′ along a timeline that illustrates operation of Short-Stop 20 in controlling power switch 100 to respond to voltage surge V₅₃₋₆₂-surge. Surge voltage is assumed to occur at a time τₒ after the shaded pulse has started and at a time τ₁ Short-Stop 20 turns ON voltage divider 40 and reduces voltage of pulse P32 from V-P32 to V-P32′ to “morph” the pulse into a reduced voltage pulse P32′ that operates to decrease current through cascode 50. Following a delay, at a subsequent time τ₂, Short-Stop 20 disables gate driver 32, which sets voltage of gate G₅₁ to signal ground 70 and prevents further generation of pulses that turn ON HEMT 51.

By way of a numerical example, under normal operation an automotive power switch, such as power switch 20, configured to provide power to an automotive electric traction motor from a high voltage power source may provide the traction motor with PWM voltage pulses for which current through cascode 50 exhibits slew rates of between 20-30 A/ns (ampere per nanosecond) and V₅₃₋₆₂ a peak voltage between 1 and 1.75 volts. A short circuit may be characterized by a slew rate of current through the cascode of between 40 and 60 A/ns and V_{T} may be set at a voltage greater than about 2 volts. Optionally, the filter cutoff frequency has a value between 5 MHz-20 MHz (megahertz). A time delay Δτₒ₁=(τ₁−τₒ) may have a value between about 25 ns-50 ns (nanoseconds) and a time delay Δτ₁₂=(τ₂−τ₁) may have a value between about 200 ns-400 ns

The staged response of Short-Stop 20 to the onset of the short circuit by first increasing Rₒₙ of HEMT 51 and then, following an advantageous latency delay, turning OFF the HEMT moderates a rate at which Short-Stop 20 reduces a surge current through cascode 50 characterizing the short circuit. Short-Stop 20 operates thereby to moderate and prevent large damaging transients that the Short-Stop may generate in turning OFF HEMT 51 in response to detection and prevention of the short circuit.

Whereas in the above description of an embodiment of the disclosure illustrates Short-Stop 20 operating to anticipate and prevent a short circuit responsive to detecting a voltage surge induced by stray inductance characterizing a transistor in a cascode, embodiments of the disclosure are not limited to detecting a surge voltage in a cascode. For example, a Short-Stop in accordance with an embodiment may be used to to control a transistor comprised in a circuit responsive to detecting a voltage surge induced by an inductance anywhere in the circuit and not necessarily in a transistor or in a cascode. Furthermore, whereas Short-Stop 20 is described as controlling gating of a HEMT n-channel D-mode transistor in response to detecting a surge voltage embodiments are not limited to such transistors. A Short-Stop in accordance with an embodiment may for example be configured to provide appropriate voltages to control a p-channel and/or an E-mode transistor in response to detecting a surge voltage.

There is therefore provided in accordance with an embodiment of the disclosure a short circuit protection circuitry comprising: a HEMT (high electron mobility transistor) comprising a source, drain, and gate controllable to be turned ON and OFF by voltage applied to the gate; a comparator having an input coupled to a high-pass filter and an output at which the comparator generates an output signal responsive to a voltage induced across an inductance if the voltage after filtering by the filter exhibits a voltage surge greater than a threshold voltage; and a voltage divider controllable to be turned ON and turned OFF to control voltage provided to the gate of the HEMT, and wherein the voltage divider is turned ON responsive to the output signal from the comparator to provide the gate with a reduced voltage that is less than an ON-threshold voltage of the HEMT.

Optionally, the short circuit protection circuitry comprises a buffer that is connected to the voltage divider and biases the gate to turn ON and turn OFF the HEMT with voltage responsive to voltage that the buffer receives from the voltage divider. Optionally the voltage divider is connected in series with a gate driver to receive voltage from the gate driver and generate responsive thereto the voltage received by the buffer. Optionally the short circuit protection circuitry comprises an enabling circuit that generates enable and disable signals to respectively enable and disable the gate driver and disables the gate driver responsive to the comparator output signal. Optionally the short circuit protection circuitry comprises a latch that receives and generates at least one output signal responsive to the comparator output signal. The voltage divider may be connected to the latch and receives a signal of the at least one signal that turns ON the voltage divider. Optionally the voltage divider comprises a transistor which the signal from the latch turns ON to connect the voltage divider to a ground and thereby to turn ON the voltage divider.

In an embodiment, the enabling circuit is connected to the latch and receives a signal of the at least one signal from the latch causes the enabling circuit to generate a disable signal that disables the gate driver. Optionally, the disable signal disables the gate driver at a second time delayed from a first time at which the voltage divider is turned ON. Optionally, the first time is delayed by between 25 ns-50 ns (nanoseconds) from a time at which the voltage surge exceeds the comparator threshold voltage. Additionally, or alternatively, the second time may be delayed from the first time by between 200 ns and 400 ns.

In an embodiment the reduced voltage is less than an ON-threshold of the HEMT by a voltage difference that is equal to between 10% and 50% of an absolute value of the ON-threshold voltage. In an embodiment voltage that biases the gate of the HEMT comprises voltage pulses. In an embodiment the HEMT is a D-mode HEMT. In an embodiment the HEMT is an E-Mode HEMT. In an embodiment the HEMT is a first transistor comprised in a cascode and is connected in series with a second transistor of the cascode. Optionally, the inductance is a stray inductance of the second transistor.

There is further provided in accordance with an embodiment of the disclosure a power switch comprising the short circuit protection circuitry according to any of any of the preceding claims.

There is further provided in accordance with an embodiment of the disclosure a power switch comprising short circuit protection circuitry, the power switch comprising: a cascode operable to provide a load with pulsed power from a power source, the cascode having a first transistor connected in series at an intermediate node to a second transistor; a gate driver that generates gate driver voltage pulses responsive to which a gate, of the first transistor is biased to turn the first transistor ON and OFF and provide pulsed power to the load; and short circuit protection circuitry comprising: a comparator connected to the second transistor via a high pass filter that receives voltage generated by current flowing through the second transistor and stray inductance of the second transistor and generates a comparator output signal that indicates when the received voltage filtered by the filter exceeds a threshold voltage; and voltage pulse control circuitry that controls the driver voltage pulses responsive to the comparator output signal.

In the description and claims of the present application, each of the verbs, “comprise” “include” and “have”, and conjugates thereof, are used to indicate that the object or objects of the verb are not necessarily a complete listing of components, elements or parts of the subject or subjects of the verb.

Descriptions of embodiments of the invention in the present application are provided by way of example and are not intended to limit the scope of the invention. The described embodiments comprise different features, not all of which are required in all embodiments of the invention. Some embodiments utilize only some of the features or possible combinations of the features. Variations of embodiments of the invention that are described, and embodiments of the invention comprising different combinations of features noted in the described embodiments, will occur to persons of the art. The scope of the invention is limited only by the claims.

1. A short circuit protection circuitry comprising:
a HEMT (high electron mobility transistor) comprising a source, drain, and gate controllable to be turned ON and OFF by voltage applied to the gate;
a comparator having an input coupled to a high-pass filter and an output at which the comparator generates an output signal responsive to a voltage induced across an inductance if the voltage after filtering by the filter exhibits a voltage surge greater than a threshold voltage; and
a voltage divider controllable to be turned ON and turned OFF to control voltage provided to the gate of the HEMT, and wherein the voltage divider is turned ON responsive to the output signal from the comparator to provide the gate with a reduced voltage that is less than an ON-threshold voltage of the HEMT.

2. The short circuit protection circuitry according to claim 1 and comprising a buffer that is connected to the voltage divider and biases the gate to turn ON and turn OFF the HEMT with voltage responsive to voltage that the buffer receives from the voltage divider.

3. The short circuit protection circuitry according to claim 2 wherein the voltage divider is connected in series with a gate driver to receive voltage from the gate driver and generate responsive thereto the voltage received by the buffer.

4. The short circuit protection circuitry according to claim 3 and comprising an enabling circuit that generates enable and disable signals to respectively enable and disable the gate driver and disables the gate driver responsive to the comparator output signal.

5. The short circuit protection circuitry according to claim 4 and comprising a latch that receives and generates at least one output signal responsive to the comparator output signal.

6. The short circuit protection circuitry according to claim 5 wherein the voltage divider is connected to the latch and receives a signal of the at least one signal that turns ON the voltage divider.

7. The short circuit protection circuitry according to claim 6 wherein the voltage divider comprises a transistor which the signal from the latch turns ON to connect the voltage divider to a ground and thereby to turn ON the voltage divider.

8. The short circuit protection circuitry according to claim 5 wherein the enabling circuit is connected to the latch and receives a signal of the at least one signal from the latch causes the enabling circuit to generate a disable signal that disables the gate driver.

9. The short circuit protection circuitry according to claim 8 wherein the disable signal disables the gate driver at a second time delayed from a first time at which the voltage divider is turned ON.

10. The short circuit protection circuitry according to claim 9 wherein the first time is delayed by between 25 ns-50 ns (nanoseconds) from a time at which the voltage surge exceeds the comparator threshold voltage.

11. The short circuit protection circuitry according to claim 9 wherein the the second time is delayed from the first time by between 200 ns and 400 ns.

12. The short circuit protection circuitry according to claim 1 wherein the reduced voltage is less than an ON-threshold of the HEMT by a voltage difference that is equal to between 10% and 50% of an absolute value of the ON-threshold voltage.

13. The short circuit protection circuitry according to claim 1 wherein voltage that biases the gate of the HEMT comprises voltage pulses.

14. The short circuit protection circuitry according to claim 1 wherein the HEMT is a D-mode HEMT.

15. The short circuit protection circuitry according to claim 1 wherein the HEMT is an E-Mode HEMT.

16. The short circuit protection circuitry according to claim 1 wherein the HEMT is a first transistor comprised in a cascode and is connected in series with a second transistor of the cascode.

17. The short circuit protection circuitry according to claim 16 wherein the inductance is a stray inductance of the second transistor.

18. A power switch comprising the short circuit protection circuitry according to claim 1.

19. A power switch comprising short circuit protection circuitry, the power switch comprising:
a cascode operable to provide a load with pulsed power from a power source, the cascode having a first transistor connected in series at an intermediate node to a second transistor;
a gate driver that generates gate driver voltage pulses responsive to which a gate, of the first transistor is biased to turn the first transistor ON and OFF and provide pulsed power to the load; and
short circuit protection circuitry comprising:
a comparator connected to the second transistor via a high pass filter that receives voltage generated by current flowing through the second transistor and stray inductance of the second transistor and generates a comparator output signal that indicates when the received voltage filtered by the filter exceeds a threshold voltage; and
voltage pulse control circuitry that controls the driver voltage pulses responsive to the comparator output signal.
